(19) United States
(12) Patent Application Publication
(10) Pub. No.: US 2011/0050308 A1
(43) Pub. Date: Mar. 3, 2011

(54) STANDBY POWER REDUCTION METHOD AND APPARATUS FOR SWITCHING POWER APPLICATIONS

(75) Inventors: Jun-Shiung Huang, Hsin-Chu City (TW); Chern-Lin Chen, Hsin-Chu City (TW); Chang-Ling Sha, Hsin-Chu City (TW); Ko-Yen Lee, Hsin-Chu City (TW)

(73) Assignee: Grenergy Opto, Inc., Hsin-Chu City (TW)

(21) Appl. No.: 12/553,398

(22) Filed: Sep. 3, 2009

(51) Int. Cl. H03K 3/02

(52) U.S. Cl. 327/198

(57) ABSTRACT

The present invention discloses a standby power reduction method and apparatus for switching power applications, the method comprising the steps of: performing a hysteresis comparison on a supply voltage to generate a selecting signal having a first state and a second state, wherein the hysteresis comparison has a high threshold voltage compared to the supply voltage when the selecting signal is at the first state, and the hysteresis comparison has a low threshold voltage compared to the supply voltage when the selecting signal is at the second state; and determining a UVLO_ON voltage according to the selecting signal, wherein the UVLO_ON voltage is equal to a first level when the selecting signal is at the first state, and the UVLO_ON voltage is equal to a second level when the selecting signal is at the second state.

### BACKGROUND OF THE INVENTION

1. Field of the Invention

The present invention relates to switching power applications, and more particularly to standby power reduction of switching power applications.

2. Description of the Related Art

In a switching power application, a PWM controller, powered by a supply voltage, is used to generate a gating signal to drive a power switch to transfer the power from input to output. During a start-up period, the supply voltage is rising gradually from a ground level, and the gating signal won't be generated until the supply voltage exceeds a high threshold voltage, called UVLO_ON voltage, wherein UVLO is an abbreviation for Under Voltage Lock Out. After the start-up period, the gating signal is continuously delivered unless an over load condition is encountered or the supply voltage falls below a low threshold voltage, called UVLO_OFF voltage. Please refer to FIG. 1, which shows the typical architecture of a switching power application. As shown in FIG. 1, the switching power application comprises a PWM controller 101, a main transformer 102, an output rectification and filtering unit 103, an NMOS transistor 104, resistors 105˜106, a capacitor 107, an auxiliary winding 108 and a diode 109.

In the architecture, the PWM controller 101, powered by a supply voltage Vcc, is used to generate a gating signal V_{G} according to a current sensing signal Vcs and a feedback signal V_{FB}, which is an error signal of an output voltage Vout with respect to a reference voltage.

The main transformer 102, having a primary side coupled to a main input voltage V_{IN} and a secondary side coupled to the output rectification and filtering unit 103, is used to transfer the power from the primary side to the secondary side.

The NMOS transistor 104, having a gate terminal coupled to the gating signal V_{G}, a drain terminal coupled to the primary side of the main transformer 102 and a source terminal coupled to the resistor 105, is used as a switch in a primary current path consisting of the primary side of the main transformer 102 and the resistor 105.

The resistor 105, connected between the source terminal and a reference ground, is used to carry a current of the primary current path to generate the current sensing signal Vcs.

The resistor 106, the capacitor 107, the auxiliary winding 108 and the diode 109 are used to generate the supply voltage Vcc, wherein the resistor 106 is connected between the main input voltage V_{IN} and the capacitor 107, and the capacitor 107 has a first plate connected to the resistor 106 and a second plate connected to the reference ground, and the auxiliary winding 108 is connected between the anode terminal of the diode 109 and the reference ground, and the cathode terminal of the diode 109 is connected to the first plate of the capacitor 107. The supply voltage Vcc is generated in a way that during the start-up period, the capacitor 107 is charged by the main input voltage V_{IN} through the resistor 106 to gradually increase the supply voltage Vcc on the first plate. When the supply voltage Vcc reaches an UVLO_ON voltage of the PWM controller 101, the PWM controller 101 will start to deliver the gating signal V_{G} to switch the NMOS transistor 104 to transfer power from the primary side of the main transformer 102 to the secondary side and to the auxiliary winding 108. The power in the auxiliary winding 108 is then rectified by the diode 109 and filtered by the capacitor 107 to form a DC level of the supply voltage Vcc.

The DC level of the supply voltage Vcc is dependent on the loading of the switching power application in that the DC level will be raised up when the loading is increasing but not exceeding the rating of the switching power application. If the loading exceeds the rating of the switching power application, an over load protection mechanism will be enabled to force the gating signal V_{G} to remain at a low level to switch off the NMOS transistor 104, and there will be no power delivered to the auxiliary winding 108. As a result, the charge on the capacitor 107 is drawn to supply the PWM controller 101 and the supply voltage Vcc will be decreasing. When the supply voltage Vcc falls to reach an UVLO off voltage, the PWM controller 101 will stop operation and the capacitor 107 will gain charges from the main input voltage V_{IN} through the resistor 106 and cause the supply voltage Vcc to rise up. If the loading is still exceeding the rating, the supply voltage Vcc will be kept rising and falling alternatively between the UVLO_OFF voltage and the UVLO_ON voltage.

As the power dissipated in the resistor 106 is the major part of the power consumption of the switching power application when the PWM controller is in a standby mode, the resistance of the resistor 106 is expected to be as large as possible to reduce the standby power consumption of the switching power application. However, since the resistance of the resistor 106 has to be under a maximum value to meet the spec of start-up period for a switching power application, for example 1 second maximum, there is difficulty in reducing the standby power consumption of switching power applications.

One solution proposed by a prior art is to use a lower UVLO_ON voltage for the PWM controller so that a larger resistance can be used for the resistor 106 without contradicting the start-up period spec of a switching power application. The lower UVLO_ON voltage can reduce the time needed for the supply voltage Vcc, generated by charging the capacitor 107 through the resistor 106, to reach the UVLO_ON voltage, so a larger resistance of the resistor 106 can be used to reduce the standby power consumption. However, when the PWM controller 101 is in operation, the lower UVLO_ON voltage may cause the NMOS transistor 104 damaged. The reason is that, when an over load protection happens, with a lower UVLO_ON voltage, a lower level of the gating signal V_{G} corresponding to a lower level of the supply voltage Vcc is applied to switch the NMOS transistor 104 to conduct a large current, and the power dissipated in the NMOS transistor 104 then will be huge due to a larger on-resistance of the NMOS transistor 104 caused by the lower level of the gating signal V_{G}.

Therefore, there is a need to provide a solution capable of reducing the standby power consumption without the risk of burning the power switch for switching power applications.

Seeing this bottleneck, the present invention proposes a novel standby power reduction method and apparatus for switching power applications by choosing two different UVLO_ON voltages for the start-up period and the operation period respectively.

### SUMMARY OF THE INVENTION

One objective of the present invention is to provide a novel standby power reduction method for switching power applications without increasing the start-up period and without the risk of burning the power switch.

Another objective of the present invention is to provide a novel standby power reduction apparatus for switching power applications without increasing the start-up period and without the risk of burning the power switch.

To achieve the foregoing objectives, the present invention provides a standby power reduction method for switching power applications, the method comprising the steps of: performing a hysteresis comparison on a supply voltage to generate a selecting signal having a first state and a second state, wherein the hysteresis comparison has a high threshold voltage compared to the supply voltage when the selecting signal is at the first state, and the hysteresis comparison has a low threshold voltage compared to the supply voltage when the selecting signal is at the second state; and determining a UVLO_ON voltage according to the selecting signal, wherein the UVLO_ON voltage is equal to a first level when the selecting signal is at the first state, and the UVLO_ON voltage is equal to a second level when the selecting signal is at the second state.

To achieve the foregoing objectives, the present invention further provides a standby power reduction apparatus for switching power applications, the apparatus comprising: a Schmitt trigger, used to perform a hysteresis comparison on a supply voltage to generate a selecting signal having a first state and a second state, wherein the hysteresis comparison has a high threshold voltage compared to the supply voltage when the selecting signal is at the first state, and the hysteresis comparison has a low threshold voltage compared to the supply voltage when the selecting signal is at the second state; and a switching unit, used to determine a UVLO_ON voltage according to the selecting signal, wherein the UVLO_ON voltage is equal to a first level when the selecting signal is at the first state, and the UVLO_ON voltage is equal to a second level when the selecting signal is at the second state.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 is the typical architecture of a switching power application.

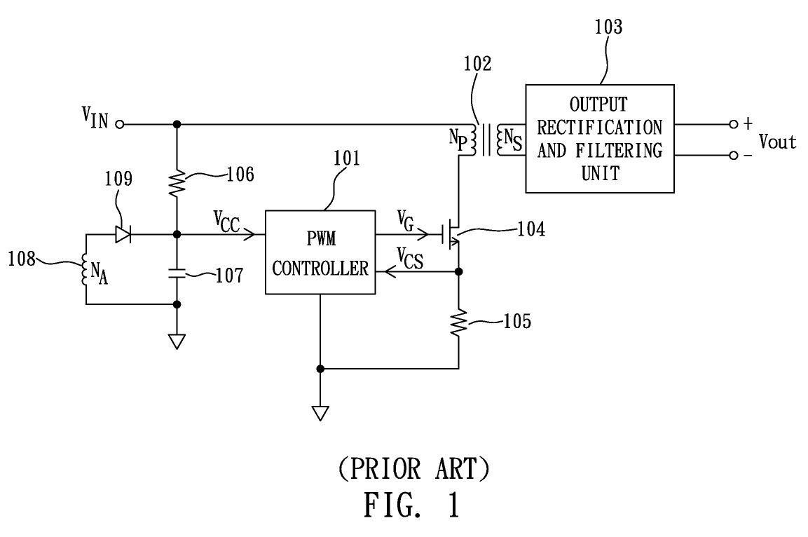

FIG. 2 is a circuit diagram of a standby power reduction apparatus according to a preferred embodiment of the present invention.

FIG. 3 is a waveform diagram of the supply voltage Vcc of FIG. 2 during start-up period, normal operation period and over-load protection period.

FIG. 4 is a flow chart diagram of a standby power reduction method for a switching power application according to a preferred embodiment of the present invention.

### DETAILED DESCRIPTION OF THE PREFERRED EMBODIMENTS

The present invention will be described in more detail hereinafter with reference to the accompanying drawings that show the preferred embodiment of the invention.

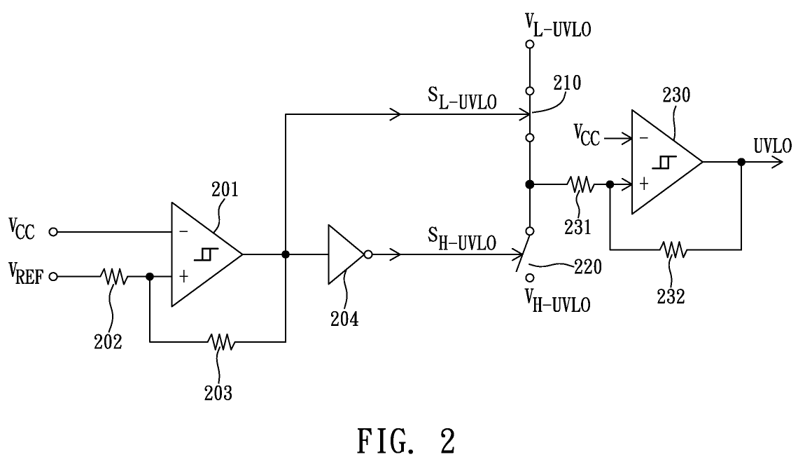

Please refer to FIG. 2, which shows a circuit diagram of a standby power reduction apparatus for a switching power application according to a preferred embodiment of the present invention. As shown in FIG. 2, the circuit comprises a comparator 201, resistors 202˜203, an inverter 204, switches 210, 220, a comparator 230 and resistors 231˜232.

In the circuit, the comparator 201 and the resistors 202˜203 are used to implement a Schmitt trigger for generate a selecting signal S_{L-UVLO} according to a supply voltage Vcc and a reference voltage V_{REF}. The comparator 201 has a negative input end connected to the supply voltage Vcc, a positive input end connected to a threshold voltage, and an output end for generating the selecting signal S_{L-UVLO}. When the selecting signal S_{L-UVLO} is at a high level, the threshold voltage at the positive input end is V_{TH3}, which is determined by superposition of the high level and the reference voltage V_{REF}, and when the selecting signal S_{L-UVLO} is at a low level, the threshold voltage at the positive input end is V_{TH1}, which is determined by superposition of the low level and the reference voltage V_{REF}.

The inverter 204 is used to invert the selecting signal S_{L-UVLO} to generate a complemented selecting signal S_{H-UVLO}. The switches 210, 220 are used to couple a low voltage V_{L-UVLO}, a high voltage V_{H-UVLO} to the comparator 230 under the control of the selecting signal S_{L-UVLO}, the complemented selecting signal S_{H-UVLO} respectively. The comparator 230, resistors 231˜232 are used to implement a Schmitt trigger to generate an indicting signal UVLO according to a supply voltage Vcc and one voltage selected from the low voltage V_{L-UVLO} or the high voltage V_{H-UVLO}. The low voltage V_{L-UVLO} is used to generate a low UVLO_ON voltage when the indicting signal UVLO is at a high level, and used to generate a low UVLO_OFF voltage when the indicting signal UVLO is at a low level. The high voltage V_{H-UVLO} is used to generate a high UVLO_ON voltage when the indicting signal UVLO is at the high level, and used to generate a high UVLO_OFF voltage when the indicting signal UVLO is at the low level. Wherein the low UVLO_ON voltage and the low UVLO_OFF voltage constitute a first hysteresis band, and the high UVLO_ON voltage and the high UVLO_OFF voltage constitute a second hysteresis band.

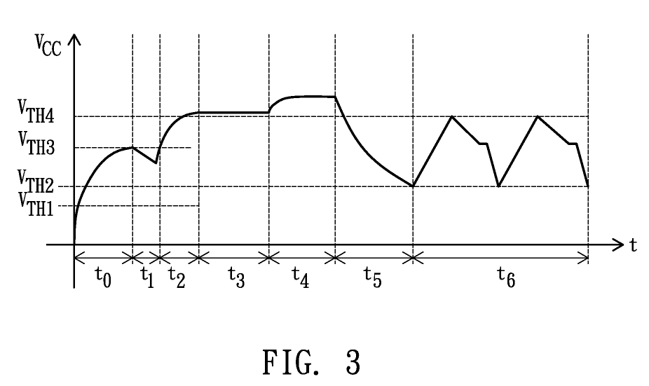

The waveform of the supply voltage Vcc during different phases of the switching power application is shown in FIG. 3. In FIG. 3, V_{TH3} is equal to the low UVLO_ON voltage; V_{TH1} is equal to the low UVLO_OFF voltage; V_{TH4} is equal to the high UVLO_ON voltage; and V_{TH2} is equal to the high UVLO_OFF voltage. When the switching power application is in the period of t₀, the supply voltage Vcc rises gradually due to a current charging a capacitor through a resistor and the supply voltage Vcc reaches the V_{TH3} at the end of the period of t₀. During t₀, since the supply voltage Vcc is rising from a low level, the selecting signal S_{L-UVLO} from the output end of the comparator 201 will be at the high level, which makes the threshold voltage at the positive input end of the comparator 201 equal to the V_{TH3}, and makes the switch 210 closed, the switch 220 open to select the low voltage V_{L-UVLO} to generate the first hysteresis band of the low UVLO_ON voltage V_{TH3} and the low UVLO_OFF voltage V_{TH1} at the positive input end of the comparator 230. During the period of t₁, the selecting signal S_{L-UVLO} from the output end of the comparator 201 will be changed to the low level, which makes the threshold voltage at the positive input end of the comparator 201 equal to the V_{TH1}, and makes the switch 210 open, the switch 220 closed to select the high voltage V_{H-UVLO} to generate the second hysteresis band of the high UVLO_ON voltage V_{TH4} and the high UVLO_OFF voltage V_{TH2} at the positive input end of the comparator 230. Besides, the dropt of the supply voltage Vcc during the period of t₁ is due to a temporary conduction of a primary side power switch. During the period of t₂, the supply voltage Vcc is gaining the power from an auxiliary winding, and when it comes to the end of the period of t₂, the supply voltage Vcc is above the V_{TH4}. The period of t₃ is corresponding to a standby mode of the switching power application, wherein the difference between the supply voltage Vcc and the V_{TH4} is quite small. The period of t₄ is corresponding to the switching power application with a heavy load, wherein the difference between the supply voltage Vcc and the V_{TH4} is bigger than that of t₃. During the period of t₅, an over load protection is encountered, and the primary side power switch is therefore turned off. The supply voltage Vcc is then decreasing until it reaches the V_{TH2}, a lower bound of the second hysteresis band, which causes the PWM controller stop operation. During the period of t₆, the switching power application is still over loaded, so when the supply voltage rises (due to a charging current through the resistor) to reach the V_{TH4}, the over load protection of the switching power application will again turn off the primary side power switch, and the supply voltage will be kept between the secondary hysteresis band up and down.

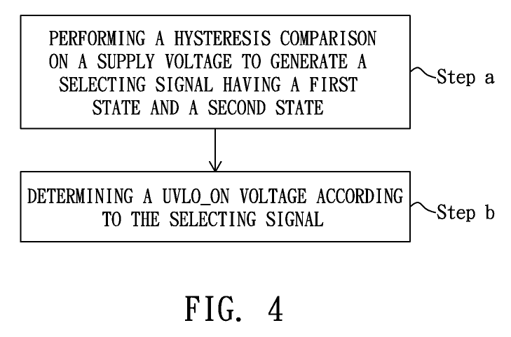

According to the specification of the circuit in FIG. 2, a standby power reduction method is further disclosed. Please refer to FIG. 4, which shows a flow chart diagram of a standby power reduction method for a switching power application according to a preferred embodiment of the present invention. As shown in FIG. 4, the flow chart includes the steps of: performing a hysteresis comparison on a supply voltage to generate a selecting signal having a first state and a second state (step a); and determining a UVLO_ON voltage according to the selecting signal (step b).

In step a, the hysteresis comparison has a high threshold voltage compared to the supply voltage when the selecting signal is at the first state, and the hysteresis comparison has a low threshold voltage compared to the supply voltage when the selecting signal is at the second state.

In step b, the UVLO_ON voltage is equal to a first level when the selecting signal is at the first state, and the UVLO_ON voltage is equal to a second level when the selecting signal is at the second state, wherein the first level is used to generate a first hysteresis band and the second level is used to generate a second hysteresis band.

Through the implementation of the present invention, a switching power application capable of using a lower hysteresis band of the UVLO voltage during the start-up period and then resuming to a normal hysteresis band of the UVLO voltage is presented. The design of the present invention permits a much larger charging resistor to be used without violating the spec of the start-up period and without reducing the voltage level of the gating signal for the primary side power switch, so the present invention does conquer the disadvantages of prior art circuits.

While the invention has been described by way of examples and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance than the conventional structure and further complies with the patent application requirements and is submitted to the Patent and Trademark Office for review and granting of the commensurate patent rights.

What is claimed is:

1. A standby power reduction method for switching power applications, said method comprising the steps of:
performing a hysteresis comparison on a supply voltage to generate a selecting signal having a first state and a second state, wherein said hysteresis comparison has a high threshold voltage compared to said supply voltage when said selecting signal is at said first state, and said hysteresis comparison has a low threshold voltage compared to said supply voltage when said selecting signal is at said second state; and
determining a UVLO_ON voltage according to said selecting signal, wherein said UVLO_ON voltage is equal to a first level when said selecting signal is at said first state, and said UVLO_ON voltage is equal to a second level when said selecting signal is at said second state.

2. The standby power reduction method for switching power applications as claim 1, wherein said supply voltage is rectified from an auxiliary winding.

3. The standby power reduction method for switching power applications as claim 1, wherein said hysteresis comparison is accomplished by a Schmitt trigger.

4. A standby power reduction apparatus for switching power applications, said apparatus comprising:
a Schmitt trigger, used to perform a hysteresis comparison on a supply voltage to generate a selecting signal having a first state and a second state, wherein said hysteresis comparison has a high threshold voltage compared to said supply voltage when said selecting signal is at said first state, and said hysteresis comparison has a low threshold voltage compared to said supply voltage when said selecting signal is at said second state; and
a switching unit, used to determine a UVLO_ON voltage according to said selecting signal, wherein said UVLO_ON voltage is equal to a first level when said selecting signal is at said first state, and said UVLO_ON voltage is equal to a second level when said selecting signal is at said second state.

5. The standby power reduction apparatus for switching power applications as claim 4, wherein said supply voltage is rectified from an auxiliary winding.
